(19) United States
(12) Patent Application Publication
(10) Pub. No.: US 2025/0098276 A1
(43) Pub. Date: Mar. 20, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kai-Chun CHANG, Pingtung City (TW); Chi-Hsun LIN, Hsinchu (TW); Yi Chen HO, Taichung (TW); Hung Cheng LIN, Hsinchu (TW)

(21) Appl. No.: 18/369,099

(22) Filed: Sep. 15, 2023

(51) Int. Cl. H01L 21/8238; H01L 27/092; H01L 29/06; H01L 29/423; H01L 29/66; H01L 29/775

(52) U.S. Cl. CPC H10D 84/038; H10D 30/014; H10D 30/43; H10D 30/6735; H10D 62/121; H10D 64/017; H10D 84/0167; H10D 84/017; H10D 84/0188; H10D 84/85

(57) ABSTRACT

Methods for forming a semiconductor device structure are described. The method includes forming first and second fin structures over a substrate and forming a dielectric wall between the first and second fin structures. The forming the dielectric wall includes depositing a first dielectric layer between the first and second fin structures, and a seam is formed in the first dielectric layer. The forming the dielectric wall further includes performing an anisotropic etch process to remove a portion of the first dielectric layer to expose the seam, performing an isotropic etch process to enlarge an opening of the seam, and the seam has a “V” shaped cross-sectional profile. The forming the dielectric wall further includes depositing a second dielectric layer between the first and second fin structures, and the seam is filled. The method further includes forming shallow trench isolation regions adjacent the first and second fin structures.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 are cross-sectional side views of various stages of manufacturing a semiconductor device structure, in accordance with some embodiments.

FIGS. 12-15 are cross-sectional side views of various stages of manufacturing a semiconductor device structure, in accordance with alternative embodiments.

FIG. 16 is a top view of one of various stages of manufacturing the semiconductor device structure, in accordance with some embodiments.

FIGS. 17A-19A are cross-sectional side views of various stages of manufacturing the semiconductor device structure taken along line A-A of FIG. 16, in accordance with some embodiments.

FIGS. 17B-19B are cross-sectional side views of various stages of manufacturing the semiconductor device structure taken along line B-B of FIG. 16, in accordance with some embodiments.

FIGS. 17C-19C are cross-sectional side views of various stages of manufacturing the semiconductor device structure taken along line C-C of FIG. 16, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

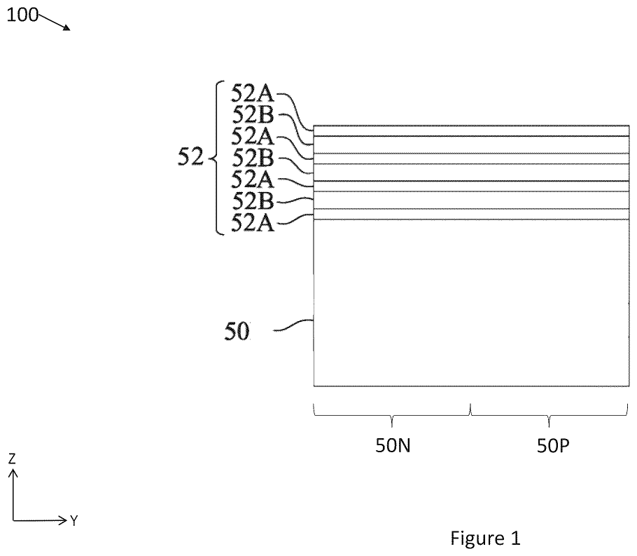

FIGS. 1-11 are cross-sectional side views of various stages of manufacturing a semiconductor device structure 100, in accordance with some embodiments. As shown in FIG. 1, the semiconductor device structure 100 includes a substrate 50 and a multi-layer stack 52 is formed over the substrate 50. The substrate 50 may be a semiconductor substrate, such as a bulk semiconductor, a semiconductor-on-insulator (SOI) substrate, or the like, which may be doped (e.g., with a p-type or a n-type dopant) or undoped. The substrate 50 may be a semiconductor wafer, such as a silicon wafer. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type field effect transistors (FETs) (NFETs), and the p-type region 50P can be for forming p-type devices, such as PMOS transistors, e.g., p-type FETs (PFETs). As discussed in greater detail below, although one n-type region 50N and one p-type region 50P are illustrated, the substrate 50 can include any desired quantity of such regions.

As shown in FIG. 1, the multi-layer stack 52 includes alternating first semiconductor layers 52A and second semiconductor layers 52B. The first semiconductor layers 52A are formed of a first semiconductor material, and the second semiconductor layers 52B are formed of a second semiconductor material different from the first semiconductor material. The semiconductor materials may each be selected from the candidate semiconductor materials of the substrate 50. In the illustrated embodiment, the multi-layer stack 52 includes four layers of each of the first semiconductor layers 52A and the second semiconductor layers 52B. It should be appreciated that the multi-layer stack 52 may include any number of the first semiconductor layers 52A and the second semiconductor layers 52B. For example, the multi-layer stack 52 may include from about three to about eight layers of each of the first semiconductor layers 52A and the second semiconductor layers 52B.

In the illustrated embodiment, the second semiconductor layers 52B will be used to form channel regions for transistors in both the n-type region 50N and the p-type region 50P. In some embodiments, the transistors are FETs, such as nanostructure FETs each having a plurality of channels wrapped around by the gate electrode layer. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel(s) of the semiconductor device structure 100 may be surrounded by the gate electrode layer. The nanostructure transistors may be referred to as nanosheet transistors, nanowire transistors, gate-all-around (GAA) transistors, multi-bridge channel (MBC) transistors, or any transistors having the gate electrode layer surrounding the channels. In some embodiments, the transistors may be planar FETs, FinFETs, complementary FETs (CFETs), forksheet FETs, or other suitable devices.

The first semiconductor layers 52A are sacrificial layers (or dummy layers), which will be removed in subsequent processing to expose the top surfaces and the bottom surfaces of the second semiconductor layers 52B in both regions. In some embodiments, the second semiconductor material of the second semiconductor layers 52B is a material suitable for both n-type and p-type nano-FETs, such as silicon, and the first semiconductor material of the first semiconductor layers 52A is a material that has a high etching selectivity from the etching of the second semiconductor material, such as silicon germanium.

Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. Each of the layers may be formed to a small thickness, such as a thickness in the range of about 5 nm to about 30 nm. In some embodiments, one group of layers (e.g., the second semiconductor layers 52B) is formed to be thinner than another group of layers (e.g., the first semiconductor layers 52A). For example, in some embodiments where the first semiconductor layers 52A are sacrificial layers (or dummy layers) and the second semiconductor layers 52B are used to form channel regions, the second semiconductor layers 52B can be thicker than the first semiconductor layers 52A. The relative thicknesses of the layers can be based on the desired channel height and the channel work function requirements of the resulting nanostructure FETs.

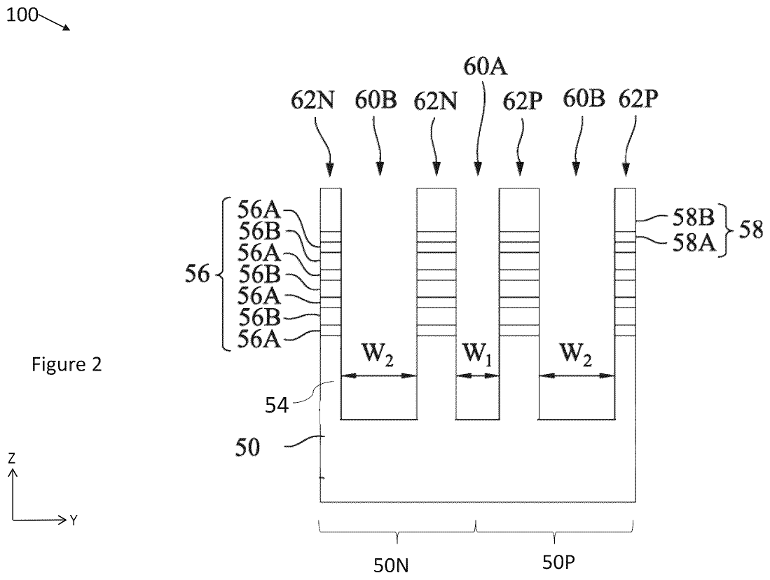

As shown in FIG. 2, trenches 60A and 60B (collectively 60) are etched in the substrate 50 and the multi-layer stack 52 to form fin structures 62 (including fin structures 62N in the n-type region 50N and fin structures 62P in the p-type region 50P). The fin structures 62 each include a semiconductor fin 54 and nanostructures 56. The semiconductor fins 54 are semiconductor strips patterned in the substrate 50. The nanostructures 56 include the remaining portions of the multi-layer stack 52 on the semiconductor fins 54. Specifically, the nanostructures 56 include alternating first nanostructures 56A and second nanostructures 56B. The first nanostructures 56A and the second nanostructures 56B are formed of remaining portions of the first semiconductor layers 52A and the second semiconductor layers 52B, respectively. In the illustrated embodiment, the second nanostructures 56B are each disposed between two of the first nanostructures 56A. The etching may be any acceptable etch process, such as a reactive ion etch (RIE), neutral beam etch (NBE), the like, or a combination thereof, and may be performed with masks 58 having a pattern of the fin structures 62. The etching may be anisotropic.

The masks 58 may be single layered masks, or may be multi-layered masks, such as multi-layered masks that each include a first mask layer 58A and a second mask layer 58B on the first mask layer 58A. The first mask layer 58A and the second mask layer 58B may each be formed from a dielectric material such as silicon oxide, silicon nitride, a combination thereof, or the like, and may be deposited or thermally grown according to acceptable techniques. The material of the first mask layer 58A may have a high etching selectivity from the etching of the material of the second mask layer 58B. For example, the first mask layer 58A may be formed of silicon oxide, and the second mask layer 58B may be formed of silicon nitride.

The fin structures 62 may be patterned by any suitable method. For example, the fin structures 62 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 62. In some embodiments, the masks 58 (or other layer) may remain on the fin structures 62.

The fin structures 62 can have widths in the range of about 5 nm to about 20 nm. The fin structures 62 in the n-type region 50N and the p-type region 50P are illustrated as having substantially equal widths for illustrative purposes. In some embodiments, the fin structures 62 in one region (e.g., the n-type region 50N) may be wider or narrower than the fin structures 62 in the other region (e.g., the p-type region 50P).

In some embodiments, the fin structures 62 are formed in adjacent pairs. Each pair of the fin structures 62 will be used to form forksheet FETs. One fin structure 62N of each pair will be used to form a n-type device, and the other fin structure 62P of each pair will be used to form a p-type device. The fin structures 62N, 62P of each pair are separated by corresponding first ones of the trenches 60A. A dielectric wall (discussed in greater detail below) will be formed in the trench 60A between the fin structures 62N, 62P of each pair, thus providing electrical isolation between the FETs of different types that will be formed in the fin structures 62N, 62P. The trenches 60A can have a first width W1 in the range of about 6 nm to about 30 nm. Adjacent pairs of the fin structures 62 are separated by corresponding second ones of the trenches 60B. The trenches 60B can have a second width W2 in the range of about 22 nm to about 46 nm. The width W2 is greater than the first width W1, so that adjacent pairs of fin structures 62 are spaced apart further than the fin structures 62N, 62P of each pair. In some embodiments, each of the trenches 60A, 60B has varying widths. For example, the width at the bottom of the trenches 60A, 60B is substantially smaller than the width at the top of the trenches 60A, 60B.

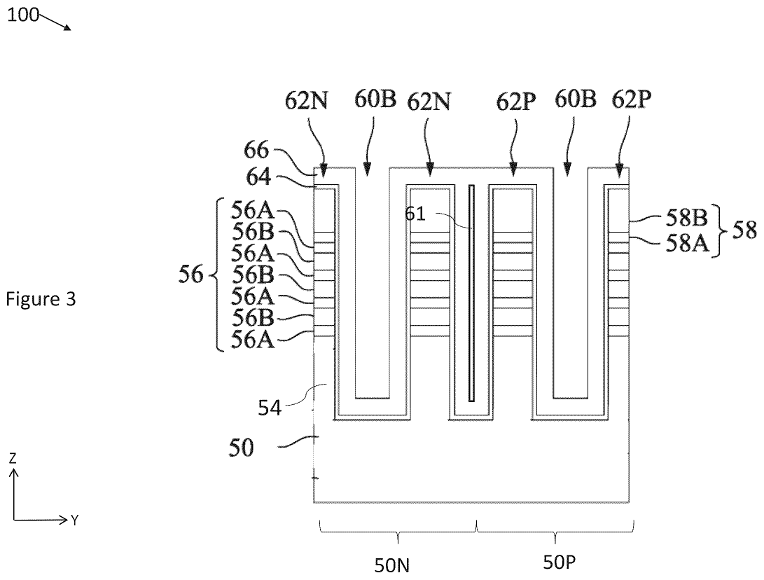

As shown in FIG. 3, a liner layer 64 is formed over the masks 58 (if present), the fin structures 62, and the substrate 50. In some embodiments, the liner layer 64 may be formed of a dielectric material, which may be formed by thermal oxidation or a conformal deposition process. Acceptable dielectric materials include low-k dielectric materials (e.g., those having a k-value of less than about 7) such as silicon oxide, silicon nitride, silicon carbonitride, silicon oxycarbide, silicon oxycarbonitride, or the like; high-k dielectric materials (e.g., those having a k-value of greater than about 7) such as hafnium oxide, zirconium oxide, zirconium aluminum oxide, hafnium aluminum oxide, hafnium silicon oxide, aluminum oxide, or the like; combinations thereof; or the like. In some embodiments, the liner layer 64 may be formed of a semiconductor material, such as silicon. The silicon may be amorphous silicon, and an anneal process may be performed after depositing the liner layer 64. Acceptable deposition processes include atomic layer deposition (ALD), chemical vapor deposition (CVD), molecular-beam deposition (MBD), physical vapor deposition (PVD), or the like. In some embodiments, the liner layer 64 can be formed to a thickness in the range of about 1 nm to about 10 nm.

A dielectric layer 66 is then formed on the liner layer 64. The dielectric layer 66 may be formed of a low-k dielectric material (such as one selected from the candidate dielectric materials of the liner layer 64), which may be deposited by a conformal deposition process (such as one selected from the candidate methods of forming the liner layer 64). In some embodiments, the dielectric layer 66 includes SiN, SiC, SiCN, AlOx, or SiOCN and has a k value ranging from about 6.5 to about 7.5. In some embodiments, the dielectric layer 66 includes SiCN and is formed by ALD. The ALD process may be a plasma enhanced ALD (PEALD) or a thermal ALD. The PEALD process may have a plasma power ranging from about 200 W to about 500 W. The thermal ALD process may have a process temperature ranging from about 600 degrees Celsius to about 700 degrees Celsius. The process pressure of the ALD process may range from about 100 Torr to about 1200 Torr. In some embodiments, the Young's modulus of the dielectric layer 66 ranges from about 55 Gpa to about 65 Gpa. In some embodiments, the dielectric layer 66 has a thickness ranging from about 7 nm to about 9 nm.

Because the trenches 60A, 60B have different widths, they are filled with different amount of dielectric material. The liner layer 64 is formed along the sidewalls and the bottoms of the trenches 60A, 60B. Because the trenches 60A have a narrower width, they are completely filled (or overfilled), with the exception of a seam 61, by the dielectric layer 66. However, because the trenches 60B have a larger width, they are not completely filled by the dielectric layer 66. In other words, after the dielectric layer 66 is deposited, the trenches 60A are filled (or overfilled), with the exception of a seam 61, but some portions of the trenches 60B remain unfilled. In some embodiments, the seam 61 is formed in the dielectric layer 66 in the trenches 60A, as shown in FIG. 3. The portions of the dielectric layer 66 formed on the fin structures 62N, 62P may merge before the trenches 60A are completely filled, and the seam 61 is formed.

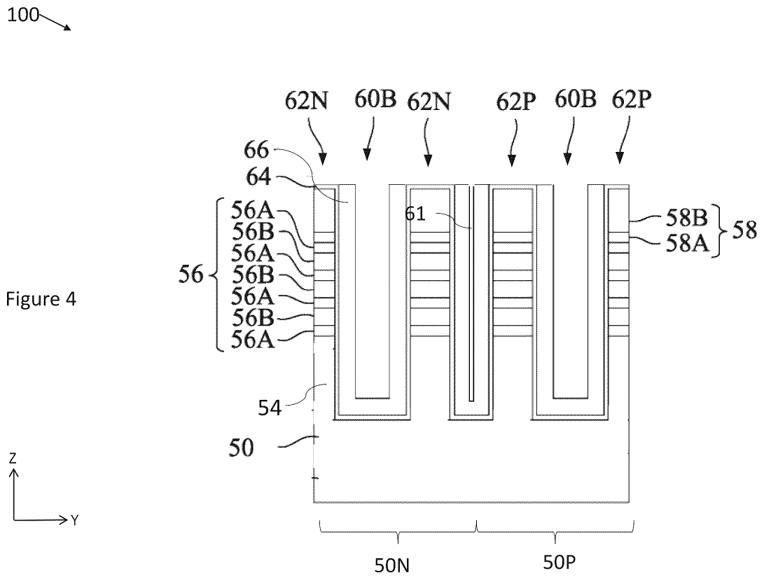

The seam 61 may lead to defective device. Thus, additional processes are performed to remove/reduce the seam 61 formed in the dielectric layer 66. In some embodiments, a first etch process is performed to remove portions of the dielectric layer 66 to expose the seam 61, as shown in FIG. 4. The first etch process may be an anisotropic etch process, such as an anisotropic dry etch process. In some embodiments, the seam 61 extends to a level of the top surface of the liner layer 64, as shown in FIG. 4. In some embodiments, the seam 61 extends to a level between the top surface of the second mask layer 58B and the bottom surface of the second mask layer 58B. In some embodiments, the first etch process may be controlled to remove just enough dielectric layer 66 to expose the seam 61.

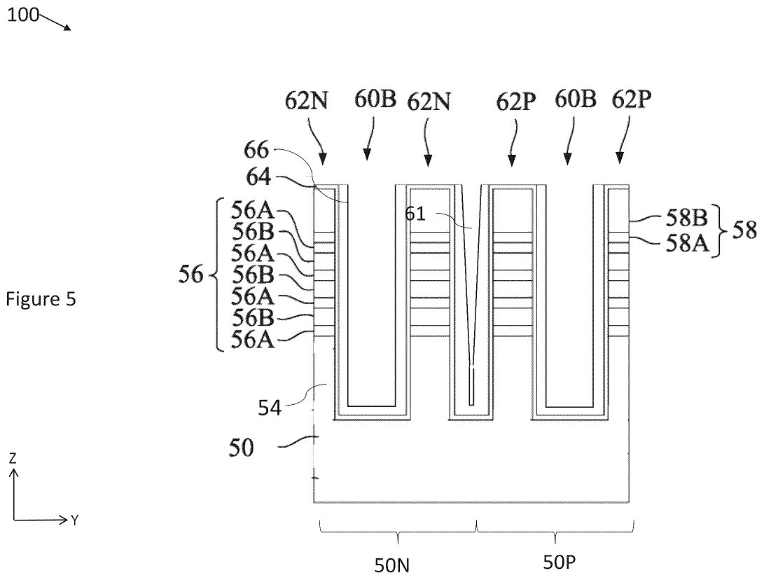

Next, as shown in FIG. 5, a second etch process is performed to increase the width of a top portion of the seam 61. In some embodiments, the second etch process is an isotropic etch process, such as a wet etch process. In some embodiments, the second etch process increases the opening of the seam 61, and the resulting seam 61 may have a “V” shaped cross-sectional profile, as shown in FIG. 5. The second etch process may also remove portions of the dielectric layer 66 located in trenches 60B. In some embodiments, a single etch process is performed to expose and enlarge the seam 61.

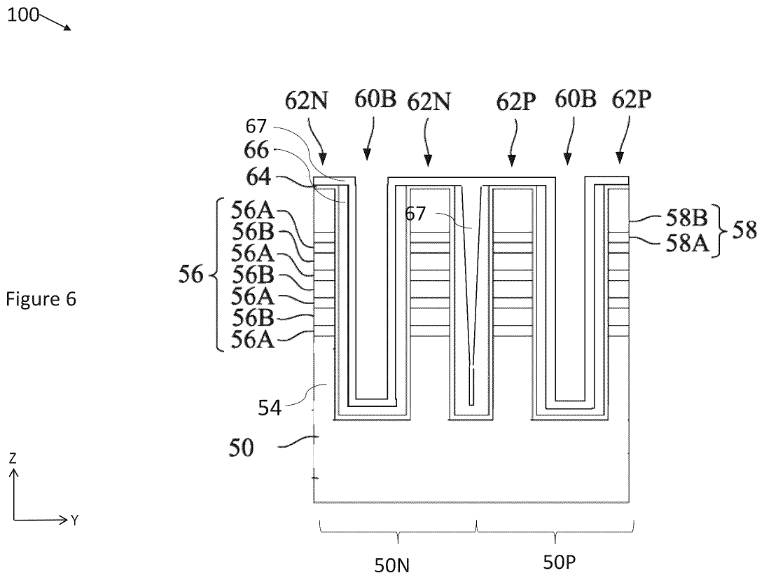

As shown in FIG. 6, a dielectric layer 67 is deposited on the semiconductor device structure 100. The dielectric layer 67 fills the seam 61 having the enlarged opening. In some embodiments, the dielectric layer 67 includes the same material as the dielectric layer 66. In some embodiments, the dielectric layer 68 includes a material different from the material of the dielectric layer 66. In some embodiments, the dielectric layer 67 includes SiCN and is formed by a conformal process, such as ALD. Because the seam 61 has the “V” shaped profile, the dielectric layer 67 can fill the seam 61 without creating another seam in the dielectric layer 67. In some embodiments, the dielectric layer 67 has a thickness ranging from about 3 nm to about 4 nm.

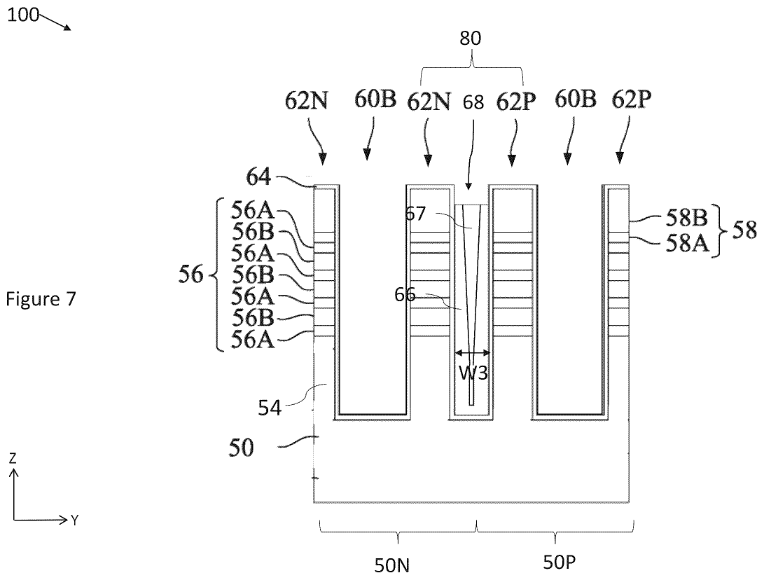

As shown in FIG. 7, the dielectric layers 66, 67 are etched back. Specifically, the portions of the dielectric layers 66, 67 in the trenches 60B and over the masks 58 (if present) or the fin structures 62 are removed by the etch back, thus reforming the trenches 60B. The dielectric layers 66, 67 are etched back using acceptable etching techniques, such as with an etching process that is selective to the dielectric layers 66, 67 (e.g., etches the material(s) of the dielectric layers 66, 67 at a faster rate than the material(s) of the liner layer 64). After the etch back is complete, the remaining portions of the dielectric layers 66, 67 are in the trenches 60A due to the small width of the trenches 60A. The remaining portions of the dielectric layers 66, 67 form dielectric walls 68 separating the fin structures 62N, 62P of each pair of the fin structures 62. The dielectric walls 68 may partially or fully fill the trenches 60A. The dielectric walls 68 can have a width W3 in the range of about 6 nm to about 30 nm. In some embodiments, the dielectric wall 68 may have varying widths. For example, the bottom of the dielectric wall 68 may have a width ranging from about 15 nm to about 20 nm, and the top of the dielectric wall 68 may have a width ranging from about 20 nm to about 26 nm. After the dielectric walls 68 are formed, forksheet structures 80 extend from the substrate 50. The forksheet structures 80 each includes a dielectric wall 68 and a pair of fin structures 62 (such as 62N and 62P), with the dielectric wall 68 disposed between the fin structures 62.

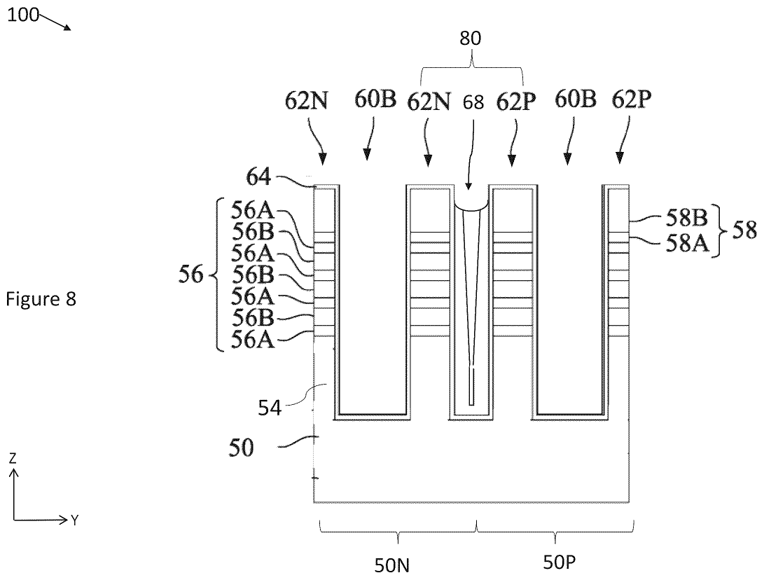

In some embodiments, the dielectric layers 66, 67 include the same material, and a single etch process may be performed to etch back the dielectric layers 66, 67. After the etch back process, the top surface of the dielectric wall 68 may be substantially flat, as shown in FIG. 7. In some embodiments, the dielectric layers 66, 67 include different materials, and two selective etch processes may be performed to etch back the dielectric layers 66, 67. For example, a first etch process selectively etches back the dielectric layer 67, and the second etch process selectively etches back the dielectric layer 66. As a result, the top surface of the dielectric wall 68 may be curved, as shown in FIG. 8. The curved top surface may be concave or convex.

As noted above, although one n-type region 50N and one p-type region 50P are illustrated, the substrate 50 can include any desired quantity of such regions. In some embodiments, each forksheet structure 80 is disposed at the boundaries of a n-type region 50N and a p-type region 50P. Further, the fin structures 62N, 62P of each forksheet structure 80 alternate. In other words, each n-type region 50N includes a first fin structure 62N from a first forksheet structure 80 and includes a second fin structure 62N from a second forksheet structure 80.

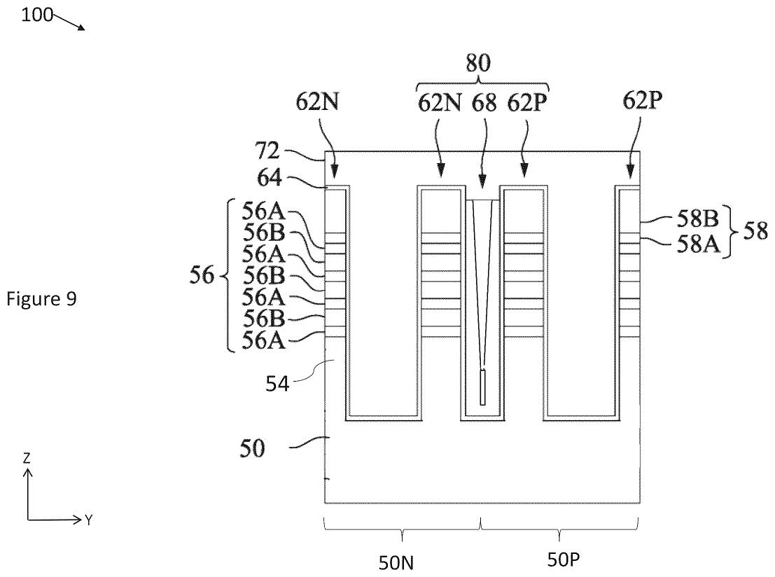

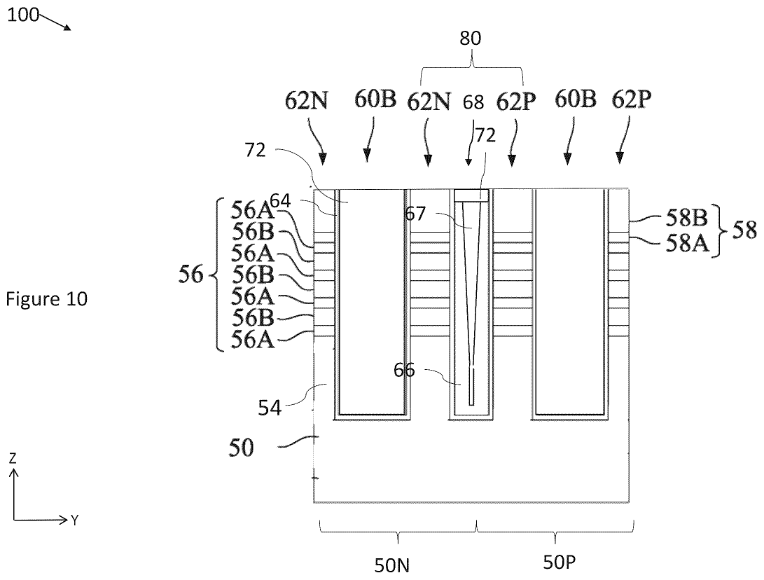

As shown in FIG. 9, an insulation material 72 is deposited over the dielectric walls 68 and the liner layer 64. The insulation material 72 fills the trenches 60B and may also be formed over the masks 58 (if present) or the fin structures 62. When the dielectric walls 68 partially fill the trenches 60A, the insulation material 72 can also be formed in the remaining portions of the trenches 60A, as shown in FIG. 9. The insulation material 72 may be an oxide such as silicon oxide, a nitride such as silicon nitride, the like, or a combination thereof, and may be formed by high-density plasma CVD (HDP-CVD), flowable CVD (FCVD), the like, or a combination thereof. Other insulation materials formed by any acceptable process may be used. An anneal process may be performed once the insulation material 72 is formed. Although the insulation material 72 is illustrated as a single layer, some embodiments may utilize multiple layers. A removal process is then applied to the insulation material 72 to remove excess material of the liner layer 64 and the insulation material 72 over the masks 58 (if present) or the fin structures 62, as shown in FIG. 10. In some embodiments, a planarization process such as a chemical mechanical polish (CMP), an etch-back process, combinations thereof, or the like may be utilized. The planarization process exposes the masks 58 or the nanostructures 56 such that top surfaces of the masks 58 or the nanostructures 56, the remaining portions of the liner layers 64, and the insulation material 72 are coplanar (within process variations) after the planarization process is complete. In the illustrated embodiment, the masks 58 remain after the planarization process. In another embodiment, the masks 58 may also be removed by the planarization process.

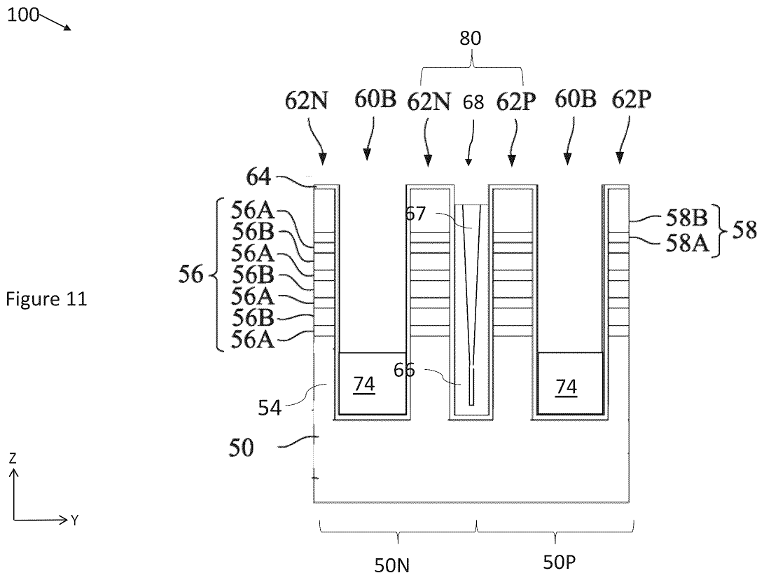

As shown in FIG. 11, the insulation material 72 is recessed to form STI regions 74, thus reforming portions of the trenches 60B. The insulation material 72 is recessed such that at least a portion of the nanostructures 56 protrude from the STI regions 74. The insulation material 72 may be recessed using an acceptable etching process, such as one that is selective to the insulation material 72 (e.g., selectively etches the material(s) of the insulation material 72 at a faster rate than the liner layer 64 and the dielectric layers 66, 67).

After the STI regions 74 are formed, the forksheet structures 80 extend from between neighboring STI regions 74. It should be appreciated that the process described above is just one example of how the forksheet structures 80 may be formed. Other acceptable processes may also be used to form the forksheet structures 80 and the STI regions 74. The forksheet structures 80 may be processed in a similar manner as semiconductor fins would be processed in a process for forming FinFETs. Processing a forksheet structure 80 in such a manner allows both n-type devices and p-type devices to be integrated in the same forksheet structure 80.

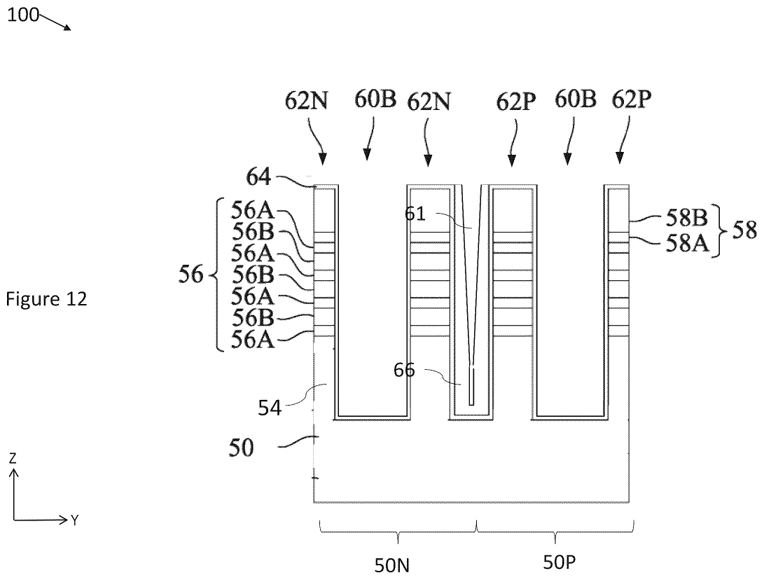

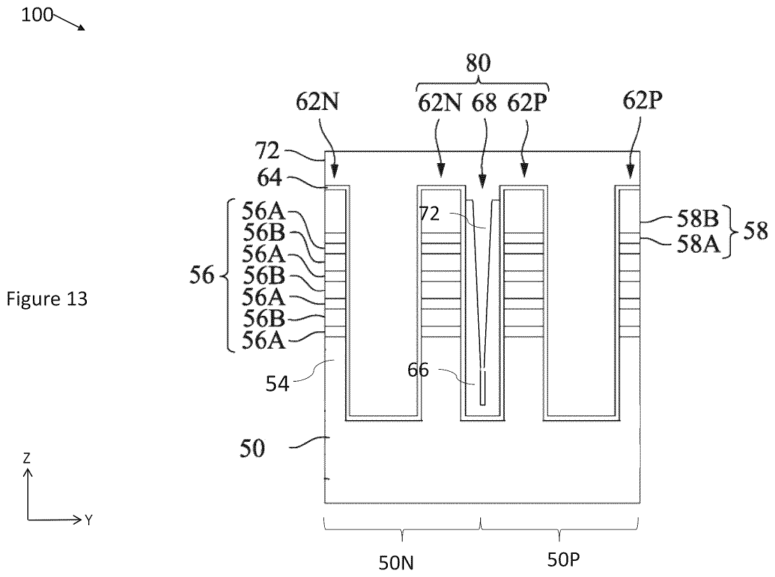

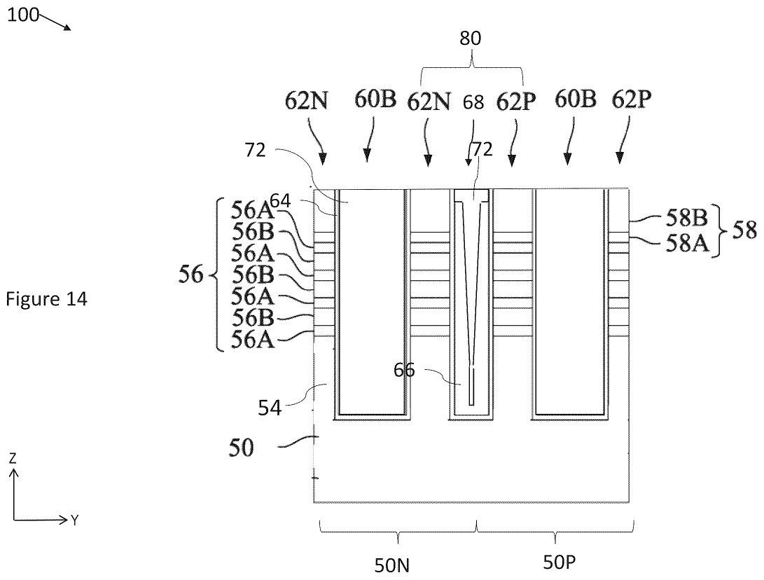

FIGS. 12-15 are cross-sectional side views of various stages of manufacturing the semiconductor device structure 100, in accordance with alternative embodiments. As shown in FIG. 12, in some embodiments, the second etch process described in FIG. 5 removes the entire dielectric layer 66 located in trenches 60B. Next, as shown in FIG. 13, the insulation material 72 fills the seam 61 having the enlarged opening and the trenches 60B. In some embodiments, the insulation material 72 includes silicon oxide and is formed by FCVD. The flowable material of the initially deposited insulation material 72 may fill the seam 61 without forming another seam in the insulation material 72 in the trenches 60A. The anneal process is then performed to anneal the flowable material and to form the insulation material 72. Next, the planarization process described in FIG. 10 is performed to remove planarize the top surface of the semiconductor device structure 100, as shown in FIG. 14.

Next, patterned mask layers (not shown) may be formed on the insulation material 72 located in the trenches 60B, while the insulation material 72 located in the trenches 60A is exposed. An implantation process is performed to implant dopants into the exposed insulation material 72 located in the trenches 60A. In some embodiments, the dopants include carbon and/or nitrogen. With the carbon and/or nitrogen implanted, the insulation material 72 located in the trenches 60A has a substantially slower etch rate compared to the insulation material 72 located in trenches 60B during the subsequent process to form the STI regions 74.

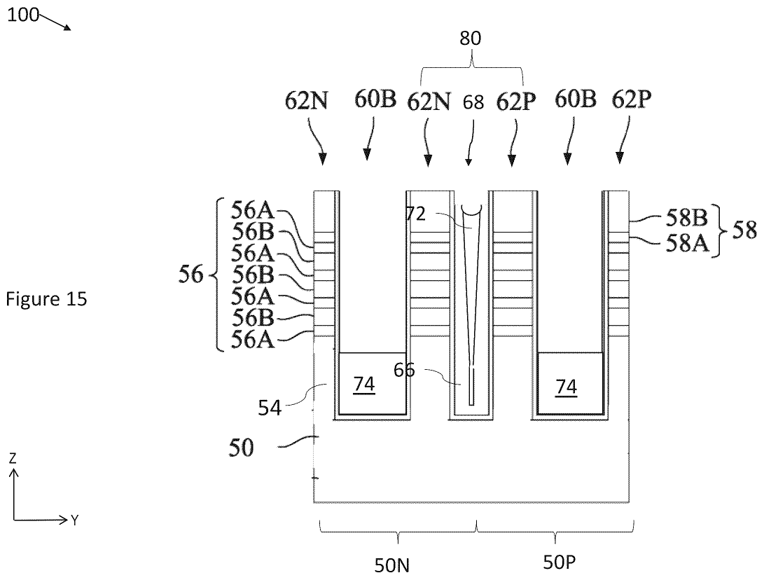

As shown in FIG. 15, the insulation material 72 located in the trenches 60B is recessed to form STI regions 74 in trenches 60B. Because the insulation material 72 located in the trenches 60A is doped with carbon and/or nitrogen and the width of the trenches 60A is substantially smaller than the width of the trenches 60B, the insulation material 72 located in the trenches 60A is not substantially affected by the process to recess the insulation material 72 located in the trenches 60B. The insulation material 72 and the dielectric layer 66 may include different materials having different etch selectivity. In some embodiments, the insulation material 72 may be recessed using an acceptable etching process, such as one that is selective to the insulation material 72 (e.g., selectively etches the material(s) of the insulation material 72 located in trenches 60B at a faster rate than the liner layer 64, the dielectric layer 66, and the insulation material 72 located in trenches 60A). As a result, the majority of the insulation material 72 located between the dielectric layer 66 remains when the STI regions 74 are formed. In some embodiments, the top surface of the insulation material 72 located in trenches 60A may have a concave profile and may be located below the level of the top surface of the dielectric layer 66 located in the trenches 60A, as shown in FIG. 15.

In some embodiments, the process to form the STI regions 74 also removes the masks 58 (if not already removed by the planarization process after the formation of the insulation material 72).

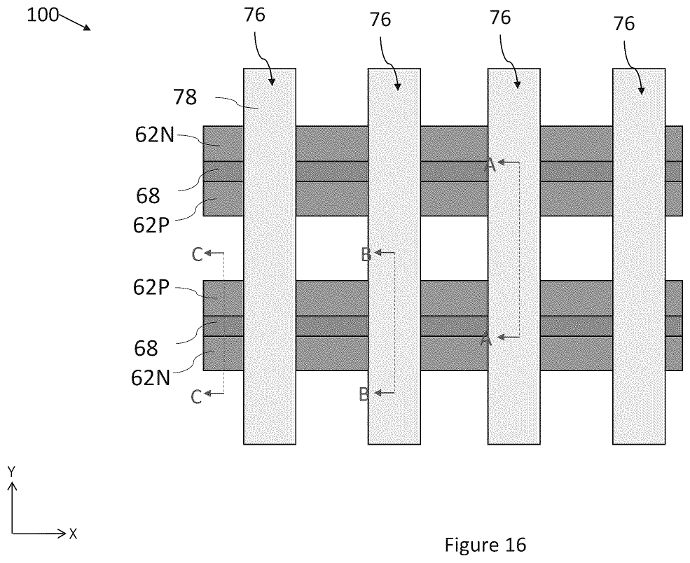

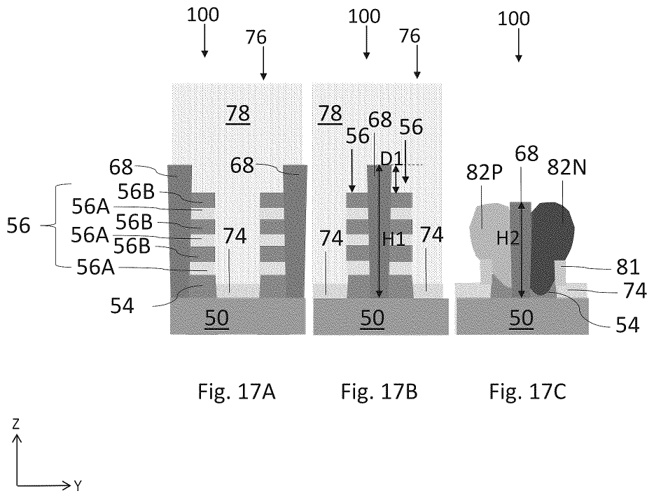

FIG. 16 is a top view of one of various stages of manufacturing the semiconductor device structure 100, in accordance with some embodiments. The details of the dielectric walls 68 are omitted in FIG. 16 for clarity. As shown in FIG. 16, one or more sacrificial gate structures 76 are formed over the semiconductor device structure 100. The sacrificial gate structures 76 are formed over portions of the fin structures 62. Each sacrificial gate structure 76 may include a sacrificial gate dielectric layer (not shown), a sacrificial gate electrode layer 78, and a mask layer (not shown). The sacrificial gate dielectric layer, the sacrificial gate electrode layer 78, and the mask layer may be formed by sequentially depositing blanket layers of the sacrificial gate dielectric layer, the sacrificial gate electrode layer 78, and the mask layer, and then patterning those layers into the sacrificial gate structures 76. Gate spacers 81 (FIG. 17C) are then formed on sidewalls of the sacrificial gate structures 76 and on sidewalls of portions of the fin structures 62 not covered by the sacrificial gate structures 76. The gate spacers 81 may be formed by conformally depositing one or more layers for the gate spacers 81 and anisotropically etching the one or more layers, for example.

The sacrificial gate dielectric layer may include one or more layers of dielectric material, such as a silicon oxide-based material. The sacrificial gate electrode layer 78 may include silicon such as polycrystalline silicon or amorphous silicon. The mask layer may include more than one layer, such as an oxide layer and a nitride layer. The gate spacer 81 may be made of a dielectric material such as silicon oxide, silicon nitride, silicon carbide, silicon oxynitride, SiCN, silicon oxycarbide, SiOCN, and/or combinations thereof.

FIGS. 17A-19A are cross-sectional side views of various stages of manufacturing the semiconductor device structure 100 taken along line A-A of FIG. 16, in accordance with some embodiments. FIGS. 17B-19B are cross-sectional side views of various stages of manufacturing the semiconductor device structure 100 taken along line B-B of FIG. 16, in accordance with some embodiments. FIGS. 17C-19C are cross-sectional side views of various stages of manufacturing the semiconductor device structure 100 taken along line C-C of FIG. 16, in accordance with some embodiments. The details of the dielectric walls 68 are omitted in FIGS. 17A to 19C for clarity. FIGS. 17A and 17B illustrate cross-sections in the channel regions under the sacrificial gate structures 76, and FIG. 17C illustrates a cross-section in the source/drain region.

As shown in FIGS. 17A, 17B and 17C, the portions of the nanostructures 56 not covered by the sacrificial gate structures 76 are recessed to expose portions of the semiconductor fins 54. The recessing of the portions of the nanostructures 56 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. In some embodiments, the recessing of the portions of the nanostructures 56 also recesses an exposed portion of the dielectric wall 68, as shown in FIG. 17C. As a result, the portions of the dielectric wall 68 located under the sacrificial gate structures 76 have a first height H1, and the portions of the dielectric wall 68 not covered by the sacrificial gate structures 76 have a second height H2 substantially less than the first height. In some embodiments, as shown in FIG. 17B, a distance D1 is between the top surface of the portion of the dielectric wall 68 under the sacrificial gate structure 76 and the top surface of the topmost second nanostructure 56B. The distance D1 may range from about 10 nm to about 20 nm.

While not shown in FIGS. 17A, 17B, and 17C, after recessing the portions of the first nanostructures 56 not covered by the sacrificial gate structures 76, the edge portions of each first nanostructures 56A are removed horizontally along the X direction. The removal of the edge portions of the first nanostructures 56A forms cavities. In some embodiments, the edge portions of the first nanostructures 56A are removed by a selective wet etch process. In cases where the first nanostructures 56A are made of SiGe and the second nanostructures 56B are made of silicon, the first nanostructures 56A can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing the edge portions of each first nanostructures 56A, a dielectric layer is deposited in the cavities to form dielectric spacers (not shown). The dielectric spacers may be made of a low-k dielectric material, such as SiON, SiCN, SiOC, SiOCN, or SiN. The dielectric spacers may be formed by first forming a conformal dielectric layer using a conformal deposition process, such as ALD, followed by an anisotropic etching to remove portions of the conformal dielectric layer other than the dielectric spacers. The dielectric spacers are protected by the second nanostructures 56B during the anisotropic etching process. The remaining first nanostructures 56A are capped between the dielectric spacers along the X direction.

As shown in FIG. 17C, source/drain (S/D) regions 82P, 82N are formed from the exposed portion of the semiconductor fins 54. The S/D regions 82P, 82N may grow both vertically and horizontally to form facets, which may correspond to crystalline planes of the material used for the semiconductor fins 54. In this disclosure, a source region and a drain region are interchangeably used, and the structures thereof are substantially the same. Furthermore, source/drain region(s) may refer to a source or a drain, individually or collectively dependent upon the context. The S/D region 82N may be made of one or more layers of Si, SiP, and SiAs for NFETs, and the S/D region 82P may be made of one or more layers of SiGe, SiGeB, and GeSn for PFETs. For PFETs, p-type dopants, such as boron (B), may also be included in the S/D regions 82P. The S/D regions 82P, 82N may be formed by an epitaxial growth method using CVD, ALD or MBE. One or more masks (not shown) may be used to form the S/D regions 82P, 82N at different times. In some embodiments, the S/D regions 82P, 82N are separated by the dielectric wall 68, as shown in FIG. 17C.

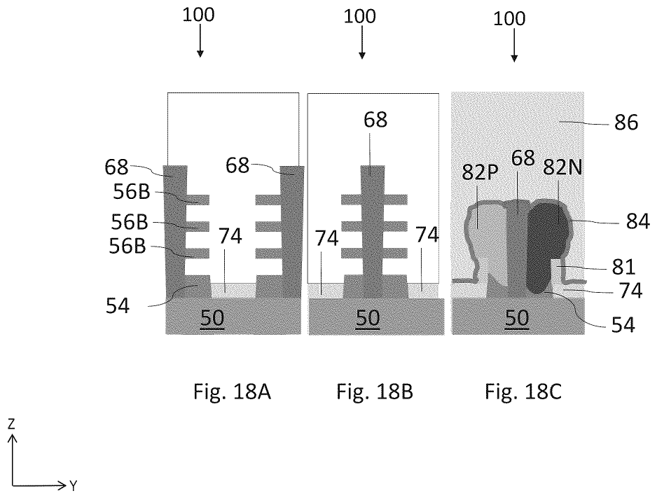

As shown in FIGS. 18A, 18B, and 18C, a contact etch stop layer (CESL) 84 is conformally formed on the exposed surfaces of the semiconductor device structure 100. The CESL 84 covers the gate spacers 81 formed on the sidewalls of the sacrificial gate structures 76, the STI regions 74, the dielectric walls 68, and the S/D regions 82P, 82N. The CESL 84 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 86 is formed on the CESL 84 over the semiconductor device structure 100. The materials for the ILD layer 86 may include compounds including Si, O, C, and/or H, such as silicon oxide, SiCOH, or SiOC. Organic materials, such as polymers, may also be used for the ILD layer 86. The ILD layer 86 may be deposited by a PECVD process or other suitable deposition technique. In some embodiments, after formation of the ILD layer 86, the semiconductor device structure 100 may be subject to a thermal process to anneal the ILD layer 86.

After the ILD layer 164 is formed, a planarization operation, such as CMP, is performed on the semiconductor device structure 100 until the sacrificial gate electrode layer 78 (FIG. 17A) is exposed. Next, the sacrificial gate structures 76 and the first nanostructures 56A are removed. The removal of the sacrificial gate structures 76 and the first nanostructures 56A forms an opening between gate spacers 81 and between second nanostructures 56B. The ILD layer 86 protects the S/D regions 82P, 82N during the removal processes. The sacrificial gate structures 76 can be removed using plasma dry etching and/or wet etching. The sacrificial gate electrode layer 78 may be first removed by any suitable process, such as dry etch, wet etch, or a combination thereof, followed by the removal of the sacrificial gate dielectric layer, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 78 but not the gate spacers 81, the ILD layer 86, and the CESL 84.

The first nanostructures 56A may be removed using a selective wet etching process. In one embodiment, the first nanostructures 56A can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

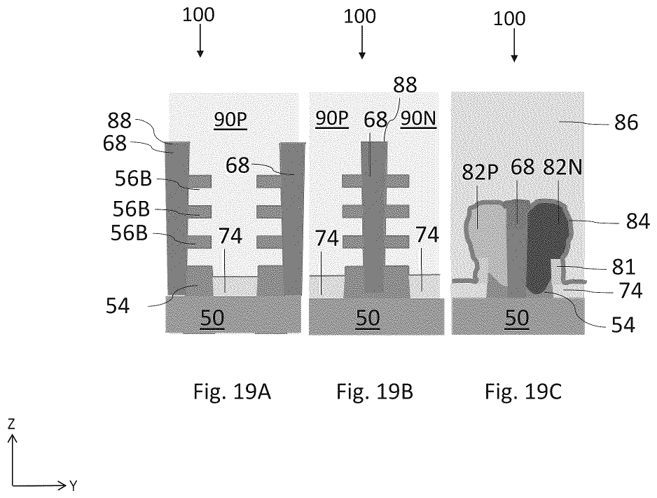

As shown in FIGS. 19A, 19B, and 19C, after the formation of the nanostructure channels (i.e., the exposed portions of the second nanostructures 56B), a gate dielectric layer 88 is formed to surround the exposed portions of the second nanostructures 56B, and gate electrode layers 90P, 90N is formed on the gate dielectric layer 88.

The gate dielectric layer 88 and the gate electrode layer 90P or 90N may be collectively referred to as a gate structure. In some embodiments, an interfacial layer (IL) (not shown) is formed between the gate dielectric layer 88 and the exposed surfaces of the second nanostructures 56B. In some embodiments, the gate dielectric layer 88 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 88 may be formed by CVD, ALD or any suitable deposition technique. The gate electrode layer 90P may include one or more layers of conductive material, such as TiN, TaN, Ru, Mo, Al, WN, TiSiN, TiTaN, TiAlN, WCN, ZrSi₂, MoSi₂, TaSi₂, NiSi₂, or other suitable materials, or any combination thereof. The gate electrode layer 90N may include one or more layers of conductive material, such as Ti, Ag, TaAl, TaAlC, TiAlN, TaC, TaCN, TaSiN, TiAl, TiTaN, Mn, Zr, other suitable N-type work function materials, or any combination thereof. The gate electrode layers 90N, 90P may be formed by CVD, ALD, electro-plating, or other suitable deposition technique. The gate electrode layers 90N, 90P may be also deposited over the upper surface of the ILD layer 86. The portions of the gate dielectric layer 88 and the gate electrode layers 90N, 90P formed over the ILD layer 86 are then removed by using, for example, CMP, until the top surface of the ILD layer 86 is exposed.

It is understood that the semiconductor device structure 100 may undergo further processes to form conductive contacts in the ILD layer 86 to be electrically connected to the S/D regions 82N, 82P and to form conductive contacts to be electrically connected to the gate electrode layers 90N, 90P. An interconnect structure may be formed over the semiconductor device structure 100 to provide electrical paths to the devices formed on the substrate 50.

The present disclosure in various embodiments provides a dielectric wall 68 electrically separating the S/D regions 82N, 82P. The dielectric wall 68 may be formed by a first deposition process, such as the ALD process, followed by a first and second etch processes, such as an anisotropic etch process and an isotropic etch process, and a second deposition process. Some embodiments may achieve advantages. For example, the first and second etch processes may increase the opening of a seam 61, as a result, the seam 61 is completely filled. The dielectric wall 68 electrically separates the S/D regions 82N, 82P.

An embodiment is a method. The method includes forming first and second fin structures over a substrate and forming a dielectric wall between the first and second fin structures. The forming the dielectric wall includes depositing a first dielectric layer between the first and second fin structures, and a seam is formed in the first dielectric layer. The forming the dielectric wall further includes performing an anisotropic etch process to remove a portion of the first dielectric layer to expose the seam, performing an isotropic etch process to enlarge an opening of the seam, and the seam has a “V” shaped cross-sectional profile. The forming the dielectric wall further includes depositing a second dielectric layer between the first and second fin structures, and the seam is filled. The method further includes forming shallow trench isolation regions adjacent the first and second fin structures.

Another embodiment is a method. The method includes forming first, second, and third fin structures over a substrate, depositing a liner layer around the first, second, and third fin structures, and depositing a dielectric layer between the first and second fin structures and between the second and third fin structures. A seam is formed in the dielectric layer between the first and second fin structures. The method further includes removing portions of the dielectric layer between the first and second fin structures to expose the seam and between the second and third fin structures to expose the liner layer and depositing an insulation material to embed the first, second, and third fin structures. The insulation material is in contact with the liner layer between the second and third fin structures, and the seam between the first and second fin structures is filled with the insulation material. The method further includes implanting a dopant into the insulation material between the first and second fin structures and performing an etch process. The insulation material between the first and second fin structures is etched at a slower rate than the insulation material between the second and third fin structures

A further embodiment is a method. The method includes forming first, second, and third fin structures over a substrate, a first trench having a first width is formed between the first and second fin structures, and a second trench having a second width substantially greater than the first width is formed between the second and third fin structures. The method further includes depositing a first dielectric layer in the first and second trenches, a seam is formed in the first dielectric layer in the first trench, and the first dielectric layer is a conformal layer. The method further includes removing portions of the first dielectric layer in the first and second trenches, and the seam in the first trench is exposed. The method further includes depositing a second dielectric layer in the first and second trenches, the seam in the first trench is filled with the second dielectric layer, and a dielectric wall including the first and second dielectric layers is formed in the first trench. The method further includes removing the first and second dielectric layers in the second trench, and a top surface of the dielectric wall is located below a level of a top surface of the first fin structure. The method further includes forming a shallow trench isolation region in the second trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming first and second fin structures over a substrate;
forming a dielectric wall between the first and second fin structures, comprising:
depositing a first dielectric layer between the first and second fin structures, wherein a seam is formed in the first dielectric layer;
performing an anisotropic etch process to remove a portion of the first dielectric layer to expose the seam;
performing an isotropic etch process to enlarge an opening of the seam, wherein the seam has a “V” shaped cross-sectional profile; and
depositing a second dielectric layer between the first and second fin structures, wherein the seam is filled; and
forming shallow trench isolation regions adjacent the first and second fin structures.

2. The method of claim 1, wherein the first dielectric layer and the second dielectric layer comprise a same material.

3. The method of claim 2, wherein the first dielectric layer and the second dielectric layer comprise SiCN, the first dielectric layer has a thickness ranging from about 7 nm to about 9 nm, and the second dielectric layer has a thickness ranging from about 3 nm to about 4 nm.

4. The method of claim 1, wherein the first dielectric layer is formed by atomic layer deposition.

5. The method of claim 4, wherein the first dielectric layer and the second dielectric layer are formed by a same process.

6. The method of claim 4, wherein the first dielectric layer and the second dielectric layer are formed by different processes.

7. The method of claim 1, further comprising forming a third fin structure over the substrate prior to forming the dielectric wall.

8. The method of claim 7, wherein the first dielectric layer and the second dielectric layer are formed between the second and third fin structures.

9. The method of claim 8, further comprising removing the first and second dielectric layers formed between the second and third fin structures prior to forming shallow trench isolation regions.

10. A method, comprising:
forming first, second, and third fin structures over a substrate;
depositing a liner layer around the first, second, and third fin structures;
depositing a dielectric layer between the first and second fin structures and between the second and third fin structures, wherein a seam is formed in the dielectric layer between the first and second fin structures;
removing portions of the dielectric layer between the first and second fin structures to expose the seam and between the second and third fin structures to expose the liner layer;
depositing an insulation material to embed the first, second, and third fin structures, wherein the insulation material is in contact with the liner layer between the second and third fin structures, and the seam between the first and second fin structures is filled with the insulation material;
implanting a dopant into the insulation material between the first and second fin structures; and
performing an etch process, wherein the insulation material between the first and second fin structures is etched at a slower rate than the insulation material between the second and third fin structures.

11. The method of claim 10, wherein the dielectric layer and the insulation material comprise different materials.

12. The method of claim 11, wherein the dielectric layer comprises SiN, SiC, SiCN, AlOx, or SiOCN, and the insulation material comprises silicon oxide.

13. The method of claim 10, wherein the liner layer comprises a semiconductor material.

14. The method of claim 10, wherein the dielectric layer is deposited by atomic layer deposition, and the insulation material is deposited by flowable chemical vapor deposition.

15. The method of claim 10, wherein a distance between the first and second fin structures is substantially smaller than a distance between the second and third fin structures.

16. The method of claim 10, wherein each of the first, second, and third fin structures comprises alternating first and second nanostructures.

17. A method, comprising:
forming first, second, and third fin structures over a substrate, wherein a first trench having a first width is formed between the first and second fin structures, and a second trench having a second width substantially greater than the first width is formed between the second and third fin structures;
depositing a first dielectric layer in the first and second trenches, wherein a seam is formed in the first dielectric layer in the first trench, and the first dielectric layer is a conformal layer;
removing portions of the first dielectric layer in the first and second trenches, wherein the seam in the first trench is exposed;
depositing a second dielectric layer in the first and second trenches, wherein the seam in the first trench is filled with the second dielectric layer, and a dielectric wall comprising the first and second dielectric layers is formed in the first trench;
removing the first and second dielectric layers in the second trench, wherein a top surface of the dielectric wall is located below a level of a top surface of the first fin structure; and
forming a shallow trench isolation region in the second trench.

18. The method of claim 17, further comprising:
forming a sacrificial gate structure over a portion of the first fin structure, a portion of the second fin structure, and a portion of the dielectric wall;
recessing exposed portions of the first fin structure, exposed portions of the second fins structure, and exposed portions of the dielectric wall;
forming first and second source/drain (S/D) regions from the recessed first and second fins, wherein the first S/D region is separated from the second S/D region by the dielectric wall; and
forming an interlayer dielectric (ILD) layer over the first and second S/D regions.

19. The method of claim 18, further comprising:
removing the sacrificial gate structure; and
forming a first gate electrode layer over the portion of the first fin structure and a second gate electrode layer over the portion of the second fin structure, wherein the portion of the dielectric wall is under the first and second gate electrode layers.

20. The method of claim 18, wherein the portion of the dielectric wall separating the first and second S/D regions has a height substantially less than a height of the portion of the dielectric wall under the first and second gate electrode.
